(19) United States
(12) Patent Application Publication
(10) Pub. No.: US 2022/0013428 A1
(43) Pub. Date: Jan. 13, 2022

(54) ELECTRONIC DEVICE

(71) Applicant: DENSO CORPORATION, Kariya-city (JP)

(72) Inventors: Hiroyoshi KUNIEDA, Kariya-city (JP); Hiroki HAYASHI, Kariya-city (JP)

(21) Appl. No.: 17/484,337

(22) Filed: Sep. 24, 2021

Related U.S. Application Data
(63) Continuation of application No. PCT/JP2020/010547, filed on Mar. 11, 2020.

(30) Foreign Application Priority Data
Mar. 28, 2019 (JP) 2019-063313

(51) Int. Cl. H01L 23/36; H01L 25/065; H01L 25/10

(52) U.S. Cl. CPC H01L 23/36; H01L 25/10; H01L 25/0657

(57) ABSTRACT

An electronic device includes an upper package, a lower package and a printed circuit board. The upper package includes an upper chip. The lower package includes a lower chip. The upper package and the lower package are stacked on the printed circuit board. The thermal diffusion layer is disposed in a vicinity of the lower chip at the lower package.

### CROSS REFERENCE TO RELATED APPLICATIONS

The present application is a continuation application of International Patent Application No. PCT/JP2020/010547 filed on Mar. 11, 2020, which designated the U.S. and claims the benefit of priority from Japanese Patent Application No. 2019-063313 filed on Mar. 28, 2019. The entire disclosures of all of the above applications are incorporated herein by reference.

### TECHNICAL FIELD

The present disclosure relates to an electronic device.

### BACKGROUND

There has been known an electronic device in which a package on package (PoP) formed by stacking two IC packages is mounted on a printed circuit board.

### SUMMARY

The present disclosure describes an electronic device including an upper package, a lower package, a printed circuit board and a thermal diffusion layer.

### BRIEF DESCRIPTION OF DRAWINGS

Objects, features and advantages of the present disclosure will become more apparent from the following detailed description made with reference to the accompanying drawings. In the drawings:

FIG. 1 is a vertical cross-sectional view showing a schematic configuration of an electronic device according to a first embodiment;

FIG. 2 is a plan view of the electronic device viewed in an upward direction, and is a conceptual view of a schematic configuration of a heat dissipation area;

FIG. 3 is a vertical cross-sectional view showing a schematic configuration of an electronic device according to a second embodiment; and

FIG. 4 is a vertical cross-sectional view showing a schematic configuration of an electronic device according to the second embodiment, and an enlarged view of region S in FIG. 3.

### DETAILED DESCRIPTION

In an electronic device, a package on package (PoP) may be formed by stacking two IC packages and may be mounted on a printed circuit board.

However, the heat generated by a lower IC package may not be fully dissipated. The situation may become remarkable when the heat generation of the lower IC package is larger than the upper IC package.

An electronic device according to an aspect of the present disclosure includes an upper package, a lower package and a printed circuit board. The upper package includes an upper chip. The lower package includes a lower chip. The upper package and the lower package are stacked on the printed circuit board. The thermal diffusion layer is disposed in a vicinity of the lower chip at the lower package.

According to the electronic device in the above aspect of the present disclosure, since the heat is efficiently transferred from the lower chip to the thermal diffusion layer, the heat can be efficiently dissipated from the lower chip. As a result, the heat dissipation of the entire electronic device can be enhanced, so that it is possible to provide an electronic device with enhanced reliability.

Hereinafter, electronic devices according to multiple embodiments of the present disclosure will be described with reference to the drawings. In the following description, the same elements as those described above are designated by the same reference numerals, and the description thereof will be omitted. In the drawings, a direction toward a metal case 14 of an electronic device 1 is defined as an upper direction or an upward direction, and a direction toward a printed circuit board 16 of the electronic device 1 is defined as a lower direction or a downward direction.

### First Embodiment

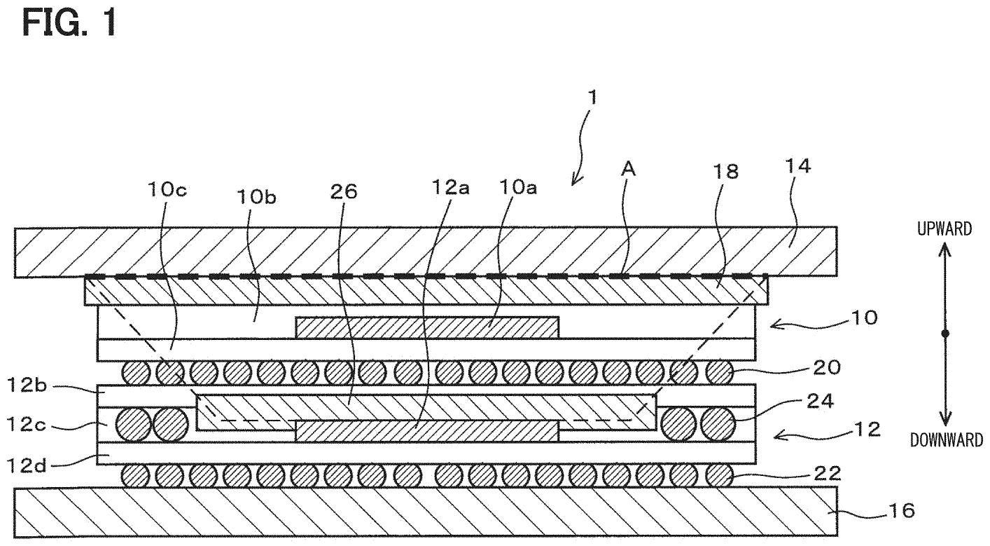

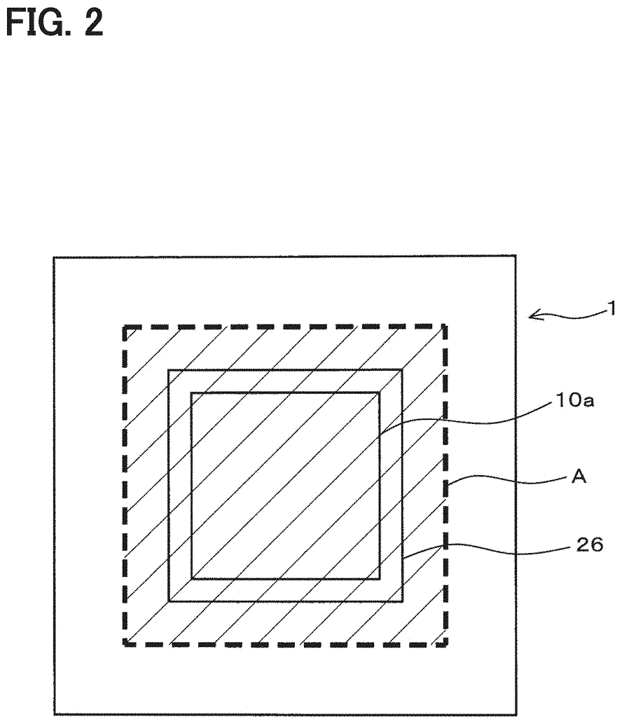

As shown in FIGS. 1, 2, the electronic device 1 according to a first embodiment is a so-called PoP in which two IC packages are stacked. The electronic device 1 includes a printed circuit board (PCB) 16, a lower package 12, an upper package 10 and a metal case 14. The metal case 14 covers the lower package 12 and the upper package 10. The electronic device 1 has a substantially rectangular flat plate shape. Each of the upper package 10 and the lower package 12 in the electronic device 1 has a substantially rectangular flat plate shape.

The upper package 10 and the lower package 12 are stacked above the printed circuit board 16. Between the upper package 10 and the lower package 12, multiple upper solder balls 20 are disposed. The upper package 10 and the lower package 12 are connected through multiple upper solder balls 20. Between the lower package 12 and the printed circuit board 16, multiple lower solder balls 22 are disposed. The lower package 12 and the printed circuit board 16 are connected through multiple lower solder balls 22.

A thermal interface material (TIM) 18 is disposed between the upper surface of the upper package 10 and an inner ceiling surface of the metal case 14. The thermal interface material 18 is made of a substance having higher thermal conductivity, and includes, for example, silicon and graphite. The thermal interface material 18 is in contact with the upper surface of the upper package 10 and the inner ceiling surface of the metal case 14, and transfers the heat from the upper package 10 to the metal case 14.

The upper package 10 includes an upper chip 10a, an upper layer 10b, and a lower layer 10c. The upper chip 10a is disposed on the lower layer 10c. The upper layer 10b covers an upper surface and a side surface of the upper chip 10a. The upper layer 10 may cover a part of the upper surface and the side surface off the upper chip 10a. The upper chip 10a is an integrated circuit in which multiple transistors, wiring, and the like are mounted on a semiconductor substrate (not shown), that is, an IC chip. The upper layer 10b is, for example, a mold resin. The lower layer 10c is, for example, a printed circuit board. The upper chip 10a has a substantially rectangular flat plate shape.

The lower package 12 includes a lower chip 12a, an upper layer 12b, an intermediate layer 12c, a lower layer 12d, and a thermal diffusion layer 26. The lower chip 12a is disposed on the lower layer 12d, and the thermal diffusion layer 26 is in contact with a portion of the upper surface and the side surface of the lower chip 12a. The thermal diffusion layer 26 is disposed at least in the vicinity of the lower chip 12a. The lateral dimension of the thermal diffusion layer 26 is larger than the lateral dimension of the lower chip 12a, and the area of the upper surface of the thermal diffusion layer 26 is larger than the area of the upper surface of the lower chip 12a. Each of the lower chip 12a and the thermal diffusion layer 26 has a substantially rectangular flat plate shape.

The intermediate layer 12c is in contact with the side surface of the lower chip 12a and a lower half of the thermal diffusion layer 26, and covers the respective side surfaces of the lower chip 12a and the thermal diffusion layer 26 and a portion of the lower surface of the thermal diffusion layer 26. The upper layer 12b is disposed on the intermediate layer 12c, and covers a portion of the upper surface and side surface of the thermal diffusion layer 26. The intermediate layer 12c includes a stack via 24 disposed at the lower chip 12a laterally to the lower chip 12a and the thermal diffusion 26, and is contact with the upper layer 12b and the lower layer 12d.

The stack via 24 is, for example, a solder ball made of a solder. For the stack via 24, lead and tin may be adopted as main components. Moreover, copper may further be added for the stack via 24. Alternatively, lead-free solder containing no lead may be adopted for the stack via 24. Alternatively, a through hole may be provided at the intermediate layer 12c, and a metal such as copper may be embedded in the through hole to form an embedded metal.

A substance with a higher thermal conductivity is adopted for the thermal diffusion layer 26, and has a higher thermal conductivity than the surrounding material such as a mold resin. The thermal diffusion layer 26 is made of, for example, a metal such as copper or a graphite. The thermal diffusion layer 26 transfer the heat generated from the lower chip 12a by having a contact with the lower chip 12a, and further dissipates the heat from the main surface of the thermal diffusion layer 26. Most of the heat dissipated from the thermal diffusion layer 26 propagates while diffusing in the upward direction with a spread with a predetermined angle. This diffused heat propagates to the metal case 14.

At this time, as illustrated in FIGS. 1, 2, an area in which the heat propagates from the lower chip 12a to the thermal diffusion layer 26 and is further transferred to the metal case 14 without losing a large amount of the heat is referred to as a heat dissipation area A. FIGS. 1, 2 illustrate that the heat dissipation area A locates at the lower surface of the metal case 14. When the heat propagates in the order of the lower chip 12a, the thermal diffusion layer 26, and the metal case 14, the area in which the heat propagates becomes larger. As view from above the electronic device 1, the heat dissipation area A is at least larger than the flat area of the lower chip 12a. As view from above the electronic device 1, the heat dissipation area A is larger than the area of the thermal diffusion layer 26. The angle at which the heat diffuses from the thermal diffusion layer 26 to the metal case 14 varies according to, for example, the material existing between the thermal diffusion layer 26 and the metal case 14. In this situation, the planar shape of the heat dissipation area A has a substantially rectangular shape reflecting on the shape of the thermal diffusion layer 26 for transferring the heat to the metal case 14.

The lower chip 12a is an integrated circuit in which multiple transistors, wiring, and the like are mounted on a semiconductor substrate (not shown). The upper layer 12b and the lower layer 12d are, for example, printed circuit boards. The intermediate layer 12c is, for example, a mold resin. The thermal conductivity of the thermal diffusion layer 26 is made to be higher than at least the intermediate layer 12c, in other words, higher than the mold resin.

According to the electronic device 1 described in the first embodiment, the following advantageous effects are obtained.

The thermal diffusion layer 26 is disposed in the vicinity of the lower chip 12a, and is in contact with the upper surface of the lower chip 12a to cover the lower chip 12a. The thermal conductivity of the thermal diffusion layer 26 is larger than the thermal conductivity of the mold resin included in the intermediate layer 12c. In this situation, the heat generated by the lower chip 12a propagates to the thermal diffusion layer 26, and is diffused from the thermal diffusion layer 26 and then arrives at the metal case 14 and is dissipated outwards. The thermal conductivity of the thermal diffusion layer 26 is larger than the thermal conductivity of the mold resin. Therefore, the heat efficiently propagates from the lower chip 12a to the thermal diffusion layer 26. As a result, the heat from the lower chip 12a is efficiently dissipated.

The area of the upper surface of the thermal diffusion layer 26 is larger than the area of the upper surface of the lower chip 12a, and the thermal diffusion layer 26 is disposed between the upper package 10 and the metal case 14. The heat generated at the lower chip 12a propagates to the thermal diffusion layer 26. In other words, the heat generated at the lower chip 12a is transferred to the thermal diffusion layer, and the heat propagated to the thermal diffusion layer 26 is dissipated from the upper surface of the thermal diffusion layer 26. The thermal diffusion layer 26 covers the top of the lower chip 12a. The area of the upper surface of the thermal diffusion layer 26 is larger than the upper surface of the lower chip 12a.

Subsequently, the heat from the thermal diffusion layer 26 spreads over the heat dissipation area A and propagates to the metal case 14. With such a configuration, the heat generated by the lower chip 12a efficiently propagates to the metal case 14 via the thermal diffusion layer 26. Therefore, the heat dissipation of the entire electronic device 1 can be enhanced. As a result, the reliability of the electronic device can be enhanced.

### Second Embodiment

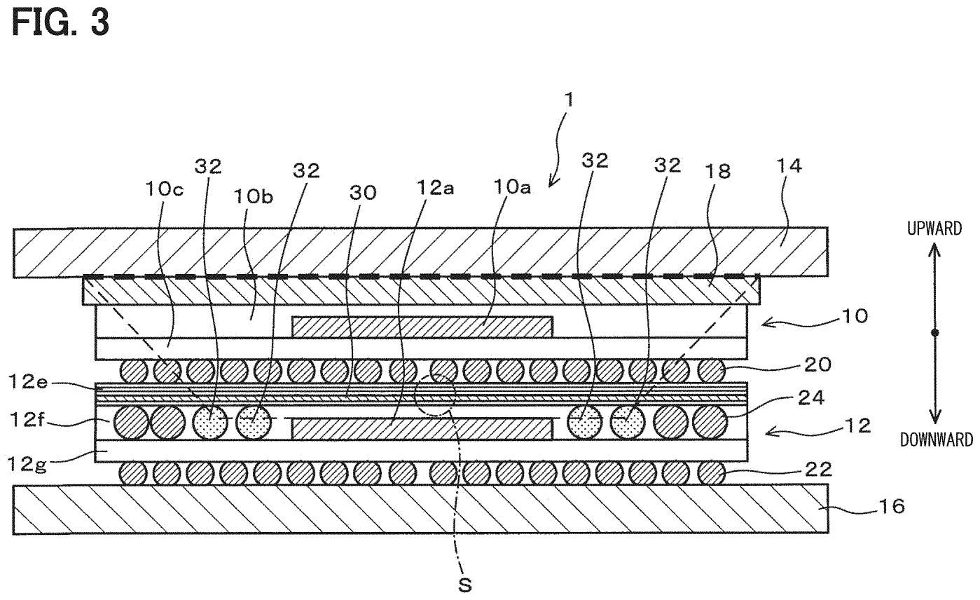

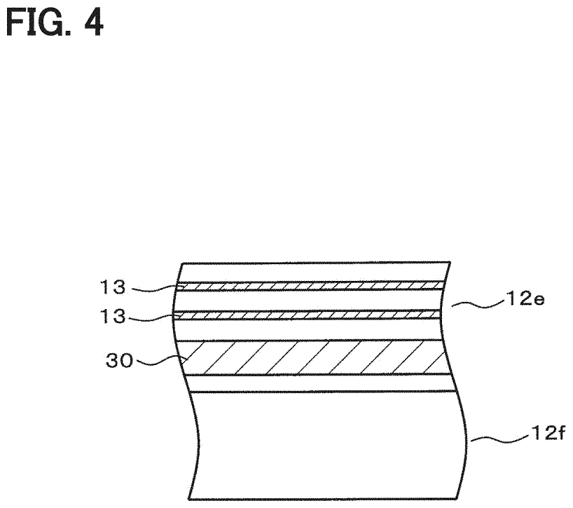

The following describes a second embodiment with reference to FIGS. 3 and 4. In the second embodiment, the electronic device 1 has substantially the same configuration as that of the first embodiment, but differs in the following points.

The lower package 12 includes a lower chip 12a, and further includes, from the top, an upper layer 12e, an intermediate layer 12f and a lower layer 12g. The lower chip 12a is disposed on the lower layer 12d. The thermal diffusion layer 30 and a thermal diffusion part 32 are disposed in the vicinity of the lower chip 12a.

As illustrated in FIGS. 3 and 4, the thermal diffusion layer 30 is included in the upper layer 12a directly above the intermediate layer 12f in the lower chip 12a. A substance with a higher thermal conductivity is adopted for the thermal diffusion layer 30. The thermal diffusion layer 30 is made of, for example, a metal such as copper or a graphite.

The upper layer 12a is a printed circuit board (PCB), and includes multiple wiring layers 13 and the thermal diffusion layer 30 inside, as illustrated in FIG. 4. The wiring layer 13 is a wiring layer included in a circuit of the upper layer 12e, which is a printed circuit board. The wiring layer 13 and the thermal diffusion layer 30 are made of the identical material. The film thickness of the thermal diffusion layer 30 is larger than the wiring layer 13. The thermal diffusion layer 30 is disposed at the lowermost layer inside the wiring layer disposed at the upper layer 12e. That is, the thermal diffusion layer 30 is made of the identical material as the wiring layer 13, and is the lowermost layer of the multiple wiring layers included in the upper layer 12e. In this situation, the thickness of the thermal diffusion layer 30 is larger than the thickness of the wiring layer 13. By increasing the thickness of the thermal diffusion layer 30, the heat transfer efficiency is enhanced. Since the size of the plane of the thermal diffusion layer 30 is larger than the area of the upper surface of the lower chip 12a, the heat propagated from the lower chip 12a can be efficiently propagated to the thermal diffusion layer 30.

In the second embodiment, the multiple thermal diffusion parts 32 are provided to penetrate the intermediate layer 13f vertically, that is, in the thickness direction. The thermal diffusion part 32 is, for example, a solder ball made of a solder. For the thermal diffusion part 32, lead and tin may be adopted as main components. Moreover, copper may further be added for the thermal diffusion part 32. Alternatively, lead-free solder containing no lead may be adopted for the thermal diffusion part 32. Alternatively, the thermal diffusion part 32 may be provided at the intermediate layer 12f, and a metal such as copper may be embedded in the through hole to form an embedded through electrode. The thermal diffusion layer 30 and the thermal diffusion part 32 have a higher thermal conductivity than the surrounding material around the thermal diffusion layer 30 and the thermal diffusion part 32 such as a mold resin.

According to the electronic device 1 described in the second embodiment, advantageous effects similar to the advantageous effects of the electronic device 1 described in the first embodiment can be obtained. Since the thermal diffusion layer 30 is configured as the wiring layer 13 included in the upper layer 12b, the thermal diffusion layer 30 may be formed with a wiring formation process. Therefore, the thermal diffusion layer 30 may be easily formed. In addition, it is possible to dispose the thermal diffusion layer 30 in the vicinity of the lower chip 12a for including the thermal diffusion layer 30 as the lowermost layer in the upper layer 12e directly above the lower chip 12a. The thickness of the thermal diffusion layer 30 can be further made larger than the thickness of the wiring layer 13. Therefore, the heat transfer efficiency from the lower chip 12a to the thermal diffusion layer 30 is enhanced, and the heat generated by the lower chip 12a efficiently propagates to the thermal diffusion layer 30.

The thermal diffusion part 32 is disposed in the vicinity of the lower chip 12a in the lateral direction. The heat generated in the lateral direction of the lower chip 12a propagates to the thermal diffusion part 32, and is transmitted from the thermal diffusion part 32 to the upper layer 12e connected to the thermal diffusion part 32 and then can be propagated to the thermal diffusion layer 30. With the presence of the thermal diffusion part 32, since the heat generated by the lower chip 12a further propagates to the metal case 14 efficiently, it is possible to further enhance the thermal dissipation ability for the entire electronic device 1.

Although the present disclosure has been described in accordance with the examples, it is understood that the present disclosure is not limited to such examples or structures. The present disclosure encompasses various modifications and variations within the scope of equivalents. In addition, various combinations and forms, and further, other combinations and forms including only one element, or more or less than these elements are also within the scope and the scope of the present disclosure.

What is claimed is:

1. An electronic device comprising:
an upper package including an upper chip;
a lower package including a lower chip;
a printed circuit board on which the upper package and the lower package are stacked; and
a thermal diffusion layer disposed in a vicinity of the lower chip at the lower package,
wherein the lower package includes an upper layer, an intermediate layer, and a lower layer,
wherein the upper layer includes a plurality of wiring layers, and
wherein the thermal diffusion layer is at least one of the wiring layers included in the upper layer.

2. The electronic device according to claim 1,
wherein the thermal diffusion layer is in contact with an upper surface of the lower chip and covers the upper surface.

3. The electronic device according to claim 1,
wherein an area of an upper surface of the thermal diffusion layer is larger than an area of an upper surface of the lower chip.

4. The electronic device according to claim 1,
wherein a thermal conductivity of the thermal diffusion layer is larger than a thermal conductivity of a mold resin.

5. The electronic device according to claim 1, further comprising:
a metal case covering an upper surface of the upper package,
wherein the thermal diffusion layer is disposed between the upper package and the metal case.

6. The electronic device according to claim 1,
wherein the thermal diffusion layer is in contact with the lower chip.

7. The electronic device according to claim 1, further comprising:
a thermal diffusion part as a through electrode disposed in a vicinity of the lower chip.

8. The electronic device according to claim 1,
wherein the upper layer is disposed directly above the lower chip.

9. The electronic device according to claim 1,
wherein a thickness of the thermal diffusion layer is larger than a thickness of at least one of the wiring layers different from the thermal diffusion layer.

10. The electronic device according to claim 1,
wherein the thermal diffusion layer is a lowermost layer inside the wiring layers.
